(19) United States
(12) Patent Application Publication
(10) Pub. No.: US 2024/0397671 A1
(43) Pub. Date: Nov. 28, 2024

(54) DISPLAY DEVICE AND METHOD FOR MANUFACTURING THE SAME

(71) Applicant: Samsung Display Co., LTD., Yongin-si (KR)

(72) Inventors: Jeongweon SEO, Yongin-si (KR); Donghwan KIM, Yongin-si (KR); Youngdo KIM, Yongin-si (KR); Junwoo YOU, Yongin-si (KR); Junyoung LEE, Yongin-si (KR); Changmoo LEE, Yongin-si (KR)

(21) Appl. No.: 18/582,115

(22) Filed: Feb. 20, 2024

(30) Foreign Application Priority Data
May 26, 2023 (KR) 10-2023-0068666

(51) Int. Cl. H05K 7/20; G06F 1/16; G06F 1/20; H05K 7/14

(52) U.S. Cl. CPC H05K 7/20481; G06F 1/1637; G06F 1/203; H05K 7/1459

(57) ABSTRACT

Provided is a display device including a display panel including a display region and a pad region adjacent to the display region. The display device includes a protective layer disposed under the display panel. The protective layer includes a first protection portion overlapping the display region and including a heat dissipation material. The protective layer includes a second protection portion overlapping at least the pad region, where the second protection portion is absent the heat dissipation material.

### CROSS-REFERENCE TO RELATED APPLICATIONS

This application claims priority to Korean Patent Application No. 10-2023-0068666, filed on May 26, 2023, and all the benefits accruing therefrom under 35 U.S.C. § 119, the content of which in its entirety is herein incorporated by reference.

### BACKGROUND

### (1) Field

The present disclosure herein relates to a display device, and more particularly, to a display device including a lower member of a display panel with improved reliability.

### (2) Description of the Related Art

A display device may be used in various multimedia devices such as, for example, televisions, mobile phones, tablet computers, or game consoles to provide a user with image information. In some cases, a display device may include a display panel that provides image information and a protective layer for protecting the display panel from the outside.

The protective layer may prevent deformation of the display panel caused by an external impact, and the protective layer may effectively emit heat generated by the display panel to protect the display panel from the outside. In some cases, to provide various functions for protecting the display panel, a structure in which a plurality of functional layers are stacked may be applied to the protective layer.

### SUMMARY

The present disclosure provides a display device with improved reliability and a method for manufacturing the same.

An embodiment of the inventive concept provides a display device including a display panel including a display region and a pad region adjacent to the display region. The display device includes a protective layer disposed under the display panel. The protective layer includes a first protection portion overlapping the display region and including a heat dissipation material. The protective layer includes a second protection portion overlapping at least the pad region, where the second protection portion is absent the heat dissipation material.

In an embodiment, the first protection portion and the second protection portion may be each directly disposed under the display panel.

In an embodiment, the heat dissipation material may include at least one of a thermally conductive metal, a carbon-based heat dissipation material, and a thermally conductive polymer.

In an embodiment, at least one of the first protection portion and the second protection portion may further include a light-blocking material.

In an embodiment, the light-blocking material may include a carbon-based material, a black pigment, or a black dye, where the carbon-based material includes graphene or graphite.

In an embodiment, at least one of the first protection portion and the second protection portion may further include a blowing agent.

In an embodiment, a thickness of the first protection portion and a thickness of the second protection portion may be each about 100 μm to about 200 μm.

In an embodiment, a thickness of the first protection portion and a thickness of the second protection portion may be substantially equal.

In an embodiment, the second protection portion may be composed of a base resin, a light-blocking material, a blowing agent, and an additive.

In an embodiment, the first protection portion and the second protection portion may not overlap each other on a plane.

In an embodiment, the first protection portion may include one end adjacent to the pad region and another end spaced apart from the one end, and the one end of the first protection portion may be in contact with the second protection portion.

In an embodiment, an average diameter of the heat dissipation material may be about 5 μm to about 200 μm.

In an embodiment, the display device may further include a circuit board electrically connected to the display panel, wherein the protective layer may be in contact with at least a portion of the circuit board.

In an embodiment, the first protection portion and the second protection portion may each further include at least one of an acrylic resin, a urethane-based resin, a fluorine-based resin, an epoxy-based resin, a polyester-based resin, a polyamide-based resin, and a silicone-based resin.

In an embodiment of the inventive concept, a display device includes a display panel including a display region and a pad region adjacent to the display region. The display device includes a protective layer disposed under the display panel. The protective layer includes a first protection portion overlapping the display region and including a heat dissipation material. The protective layer includes a second protection portion overlapping at least the pad region, wherein the second protection portion is composed of a base resin, a light-blocking material, a blowing agent, and an additive.

In an embodiment of the inventive concept, a method for manufacturing a display device includes providing a display panel including a display region and a pad region adjacent to the display region, forming a first protection portion by supplying a first resin onto a lower surface of the display panel, wherein the first protection portion overlaps the display region, and forming a second protection portion by supplying a second resin onto the lower surface of the display panel, wherein the second protection portion overlaps at least the pad region. The first resin includes a heat dissipation material, and the second resin is absent the heat dissipation material.

In an embodiment, the forming of the first protection portion may include applying the first resin onto the lower surface of the display panel, and curing the first resin.

In an embodiment, the forming of the second protection portion may include applying the second resin onto the lower surface of the display panel, and curing the second resin.

In an embodiment, the second resin may be composed of a base resin, a light-blocking material, a blowing agent, and an additive.

In an embodiment, the method for manufacturing a display device may further include, before the forming of the second protection portion, electrically connecting a circuit board to the display panel, and determining, through the lower surface of the display panel, whether or not the circuit board is normally mounted.

### BRIEF DESCRIPTION OF THE FIGURES

The accompanying drawings are included to provide a further understanding of the inventive concept, and are incorporated in and constitute a part of this specification. The drawings illustrate example embodiments of the inventive concept and, together with the description, serve to explain principles of the inventive concept. In the drawings:

FIG. 1 is a perspective view of a display device according to an embodiment of the inventive concept;

FIG. 2 is an exploded perspective view of a display device according to an embodiment of the inventive concept;

FIG. 3 is a cross-sectional view of a display device according to an embodiment of the inventive concept;

FIG. 4 is a cross-sectional view of a display panel according to an embodiment of the inventive concept;

FIG. 5A is an enlarged cross-sectional view of portion AA illustrated in FIG. 3;

FIG. 5B is an enlarged cross-sectional view of portion BB illustrated in FIG. 3;

FIG. 6 is a flowchart illustrating a method for manufacturing a display device according to an embodiment; and

FIGS. 7A to 7E are diagrams schematically illustrating operations of a method for manufacturing a display device according to an embodiment.

### DETAILED DESCRIPTION

In this specification, when a component (or region, layer, portion, etc.) is referred to as “on”, “connected”, or “coupled” to another component, it means that it is placed/connected/coupled directly on the other component or a third component can be disposed between them.

In the present application, “directly disposed” may mean that there is no layer, film, region, plate, etc. added between a portion such as, for example, a layer, film, region, or plate and another portion. For example, “directly disposed” may mean placing two layers or two members without using an additional member such as, for example, an adhesive member therebetween.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as, for example, “below”, “lower”, “above”, and “upper” are used to describe the relationship between components shown in the drawings. The terms are relative concepts and are described based on the directions indicated in the drawings.

Terms such as, for example, “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted in ideal or overly formal meanings unless explicitly defined herein.

Hereinafter, embodiments of the inventive concept will be described with reference to the drawings.

In accordance with one or more embodiments of the present disclosure, a display device in which a single protective layer integrally having various functions and protecting the display panel is used, and a method for manufacturing the same are described.

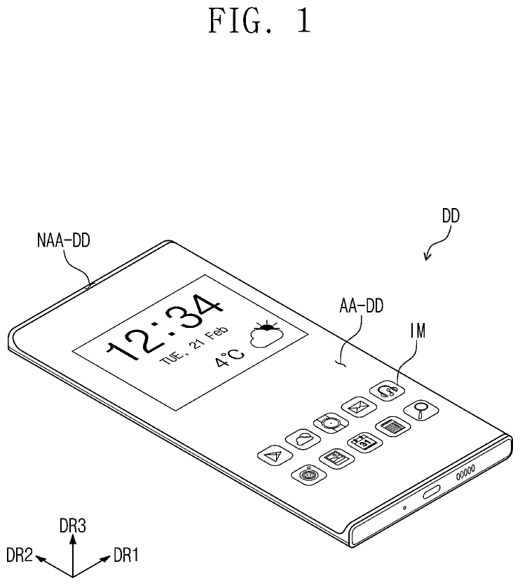

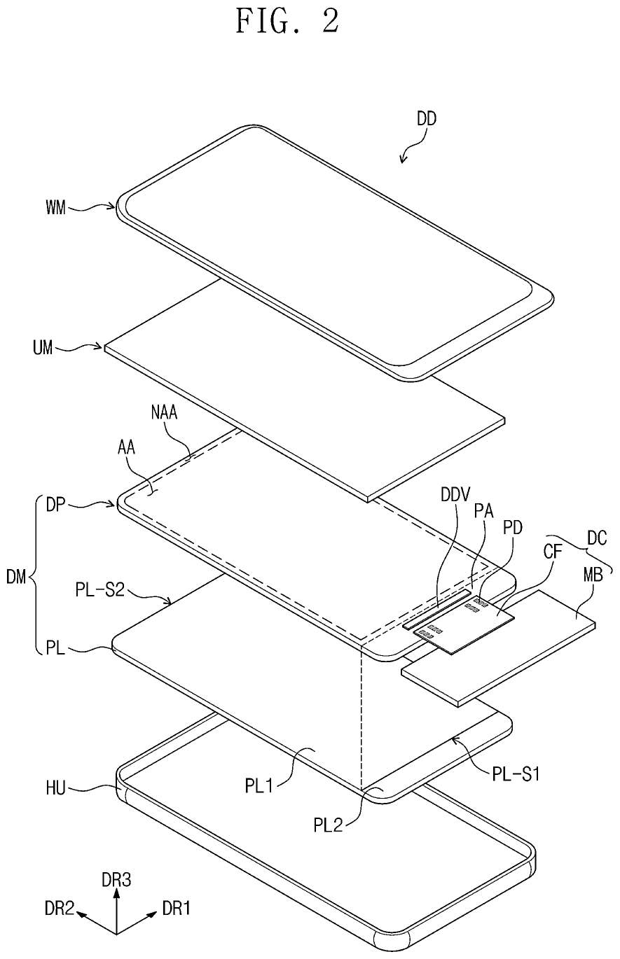

FIG. 1 is a perspective view of a display device DD according to an embodiment of the inventive concept. FIG. 2 is an exploded perspective view of the display device DD according to an embodiment of the inventive concept.

FIG. 1 illustrates an example in which the display device DD is a mobile phone. However, the display device DD is not limited thereto, and the display device DD may be a small- or medium-sized display device such as, for example, a tablet computer, a car navigation system, a game console, a wearable device, or a camera.

The display device DD may display an image IM through an active region AA-DD. The active region AA-DD may include a flat surface defined by a first direction DR1 and a second direction DR2. The active region AA-DD may further include a curved surface bent from at least one side of the flat surface defined by the first direction DR1 and the second direction DR2. In the example embodiment illustrated in FIG. 1, it is illustrated that the display device DD according to includes two curved surfaces respectively bent from both side surfaces of the flat surface defined by the first direction DR1 and the second direction DR2. However, a shape of the active region AA-DD is not limited thereto. For example, the active region AA-DD may include the flat surface, without including curved surfaces of the flat surface. In some additional and/or alternative embodiments, the active region AA-DD may include the flat surface and at least two curved surfaces of the flat surface. For example, the active region AA-DD may include four curved surfaces respectively bent from four side surfaces of the flat surface.

FIG. 1 and the following drawings illustrate the first direction DR1 to a third direction DR3, and directions indicated by the first to third directions DR1, DR2, and DR3 described in the present disclosure are relative concepts, and may thus be changed to other directions.

In the present disclosure, the first direction DR1 and the second direction DR2 may be orthogonal to each other, and the third direction DR3 may be a normal direction of the plane defined by the first direction DR1 and the second direction DR2. For example, the third direction D3 may cross or be perpendicular to the plane defined by the first direction DR1 and the second direction DR2. In the present disclosure, the wording, “on a plane” may mean when seen on the plane defined by the first direction DR1 and the second direction DR2, and a thickness direction may mean the third direction DR3, which is the normal direction of the plane defined by the first direction DR1 and the second direction DR2.

The display device DD may include the active region AA-DD and a peripheral region NAA-DD adjacent to the active region AA-DD. The active region AA-DD may correspond to a display region AA of a display panel DP to be described later, and the peripheral region NAA-DD may correspond to a non-display region NAA of the display panel DP.

The peripheral region NAA-DD may be a region blocking an optical signal, and thus may be disposed outside the active region AA-DD such that the peripheral region NAA-DD surrounds the active region AA-DD. For example, the peripheral region NAA-DD may be formed of a material that prevents the transmission of optical signals (e.g., light). In an embodiment, the peripheral region NAA-DD may be disposed on a side surface of the display device DD, and not on a front surface of the display device DD. In an embodiment, the peripheral region NAA-DD may be omitted.

The display device DD according to an embodiment may include a window WM, a housing HU, a display module DM, a circuit board DC, and an upper member UM.

The display device DD according to an embodiment may include the window WM disposed on the display panel DP. The window WM may serve as an outer surface of the display device DD. Although not illustrated, the window WM may include a base substrate, and the window WM may further include functional layers such as, for example, an anti-reflective layer, an anti-fingerprint layer, or an optical layer that controls a phase.

In the display device DD according to an embodiment, the upper member UM may be disposed under the window WM and on top of the display module DM. The upper member UM may include an anti-reflective layer and an input sensing sensor. The anti-reflective layer lowers external light reflectance. The input sensing sensor is capable of sensing a user's external input. The upper member UM may further include an adhesive layer that bonds the anti-reflective layer and the input sensing sensor.

In the display device DD according to an embodiment, the display module DM may be disposed under the upper member UM. The display module DM may include the display panel DP and a protective layer PL.

The display panel DP may include the display region AA that displays an image IM and the non-display region NAA adjacent to the display region AA. That is, for example, a front surface of the display panel DP may include the display region AA and the non-display region NAA. The display region AA may be a region activated in response to an electrical signal.

The non-display region NAA may be adjacent to the display region AA. The non-display region NAA may surround the display region AA. In some examples, a driving circuit or driving wire for driving the display region AA, various signal lines or pads that supply an electrical signal to the display region AA, an electronic element, or the like may be disposed in the non-display region NAA.

The non-display region NAA may include a pad region PA defined on an edge of the non-display region NAA. The pad region PA may be a region connected to a flexible board CF. The non-display region NAA of the display panel DP may include the pad region PA defined on one side of the non-display region NAA in the second direction DR2. Although not illustrated, in some embodiments, a plurality of signal wires (not shown) may be formed in the pad region PA. The display panel DP may be electrically connected to an external element through the pad region PA.

FIG. 2 illustrates a state in which the flexible board CF is unfolded, but aspects of the present disclosure are not limited thereto. For example, as described with reference to FIG. 1, the flexible board CF may be bent in a state in which the display device DD is coupled or folded. Accordingly, for example, in the bent state, the main board MB may be disposed under the display panel DP. FIG. 2 illustrates an example in which a driving chip DDV is mounted on the non-display region NAA of the display panel DP, but embodiments supported by aspects of the present disclosure are not limited thereto, and the driving chip DDV may be mounted on the circuit board DC. Alternatively, the driving chip DDV may be mounted on the main board MB. The mounted driving chip DDV may serve to drive the display device DD.

The flexible board CF may connect the display panel DP and the main board MB. The flexible board CF may electrically connect the display panel DP and the main board MB. Specifically, for example, one end of the flexible board CF may be connected to the display panel DP, and the other end of the flexible board CF may be connected to the main board MB. At least a portion of the flexible board CF may be bendable. Although a single flexible board CF is illustrated in the example of FIG. 2, the number flexible boards CF supported by aspects of the present disclosure is not limited thereto. For example, according to another embodiment of the inventive concept, the display device DD may include a plurality of flexible boards CF which connect the display panel DP and the main board MB.

The display panel DP may include a light-emitting element layer DP-ED (see FIG. 4) including an organic light-emitting element, a quantum-dot light-emitting element, a micro-LED light-emitting element, a nano-LED light-emitting element, or the like. The light-emitting element layer DP-ED (see FIG. 4) may be a component capable of substantially generating an image. For example, the light-emitting element layer DP-ED (see FIG. 4) may be a component that substantially generates an image.

The display device DD may include the circuit board DC connected to the display panel DP. The circuit board DC may include the flexible board CF and the main board MB. The flexible board CF may include an insulating film and conductive wires mounted on the insulating film. The conductive wires may be connected to the pads PD to electrically connect the circuit board DC and the display panel DP. For example, the conductive wires may be connected to the pads PD and may electrically connect the circuit board DC and the display panel DP. In some embodiments, the flexible board CF may be omitted, and then the main board MB may be directly connected to the display panel DP.

The main board MB may include signal lines and electronic elements which are not illustrated herein. The electronic elements may be connected to the signal lines to be electrically connected to the display panel DP. For example, the electronic elements may be connected to the signal lines and electrically connected to the display panel DP. The electronic elements generate various electrical signals, for example, a signal for generating an image IM or a signal for sensing an external input, or process a sensed signal. In some examples, the main board MB may be provided in plurality, in which a plurality of main boards MB respectively correspond to electrical signals to be generated and processed, and aspects of the main board MB are not limited to any one embodiment.

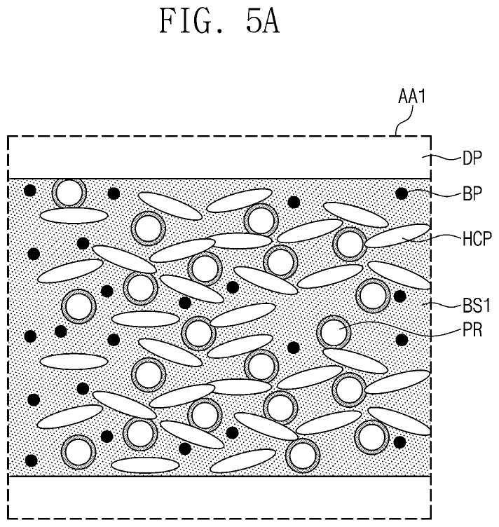

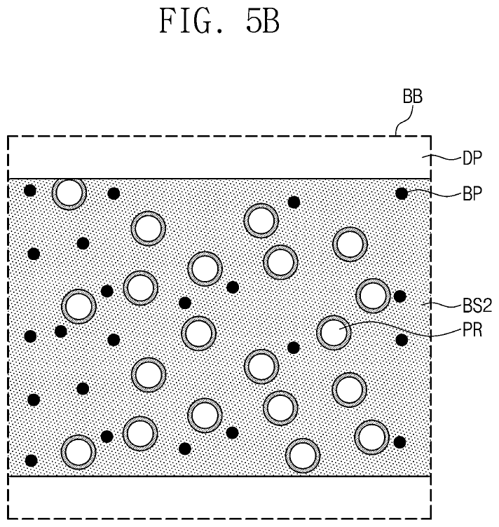

The protective layer PL may be disposed under the display panel DP. The protective layer PL may be a member that supports the display panel DP, and the protective layer PL may perform a heat dissipation function of dissipating heat generated in the display panel DP. Detailed descriptions of the protective layer PL will be made later herein with reference to FIG. 5A and the following diagrams.

The display device DD according to an embodiment may include a housing HU disposed under the protective layer PL. The display panel DP or the like may be accommodated in the housing HU. In the display device DD, according to an embodiment, the window WM may be coupled to the housing HU to constitute an exterior of the display device DD.

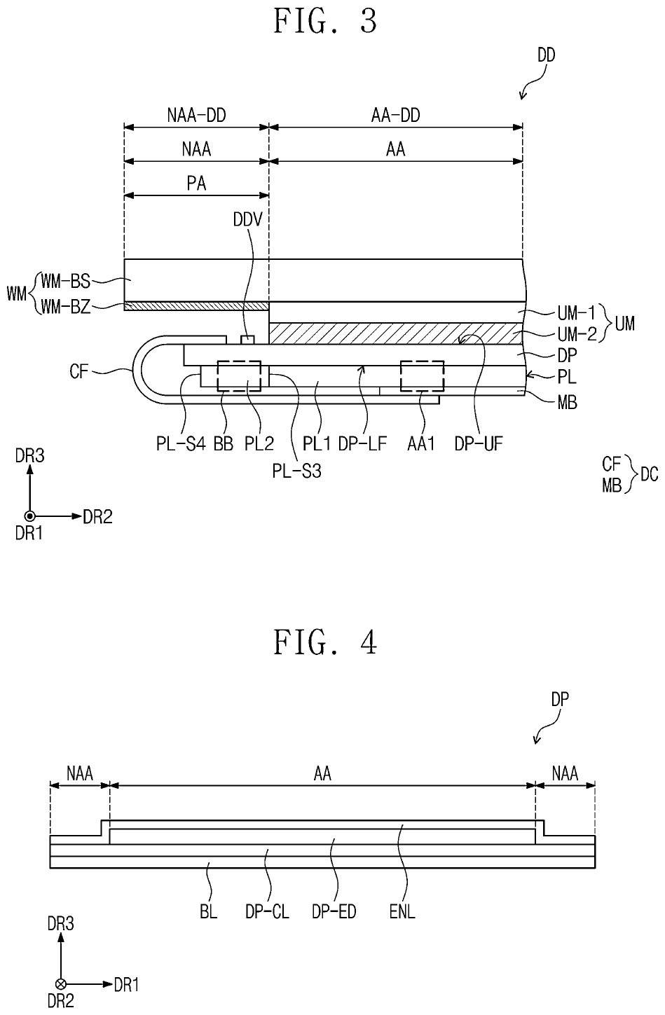

FIG. 3 is a cross-sectional view illustrating a partial configuration of a display device DD according to an embodiment of the inventive concept.

Referring to FIG. 3, the display device DD according to an embodiment of the inventive concept may include a window WM, an upper member UM, a display panel DP, and a protective layer PL.

In an embodiment, the window WM may cover a front surface of the display panel DP. The window WM may include a base substrate WM-BS and a bezel pattern WM-BZ. The base substrate WM-BS includes a transparent base layer such as, for example, a glass substrate or a transparent film.

The bezel pattern WM-BZ overlaps the non-display region NAA illustrated in FIG. 2. The bezel pattern WM-BZ may be disposed on one surface of the base substrate WM-BS. FIG. 3 illustrates an example in which the bezel pattern WM-BZ is disposed on a lower surface of the base substrate WM-BS. However, embodiments supported by aspects of the present disclosure are not limited thereto, and the bezel pattern WM-BZ may be disposed on an upper surface of the base substrate WM-BS. The bezel pattern WM-BZ may have a multi-layered structure. The multilayered structure may include a color layer and a black light-blocking layer. The color layer and the black light-emitting layer may be formed through deposition, printing, or coating. In some embodiments, the bezel pattern WM-BZ may be omitted from the window WM. For example, the bezel pattern WM-BZ may be formed on the upper member UM, not on the base substrate WM-BS.

In an embodiment, the upper member UM includes an anti-reflective layer UM-1 and an input sensor UM-2.

The anti-reflective layer UM-1 may lower external light reflectance. The anti-reflective layer UM-1 may include a retarder and/or a polarizer. The anti-reflective layer UM-1 may include a polarizing film or color filters. The color filters may have a predetermined arrangement. For example, an arrangement of the color filters may be determined in consideration of light-emitting colors of pixels included in the display panel DP. The anti-reflective layer UM-1 may further include a division layer adjacent to the color filters.

The input sensor UM-2 may include a plurality of sensing electrodes (not shown) for sensing an external input, trace lines (not shown) connected to the plurality of sensing electrodes, and an inorganic layer and/or an organic layer for insulating/protecting the plurality of sensing electrodes or the trace lines. In some embodiments, the input sensor UM-2 may be a capacitive sensor, but is not limited thereto.

In an example of manufacturing the display panel DP, the input sensor UM-2 may be directly formed, through a continuous process, on an encapsulation layer ENL to be described later with reference to FIG. 4. However, embodiments supported by aspects of the present disclosure are not limited thereto, and the input sensor UM-2 may be manufactured as a panel separate from the display panel DP, and the input sensor UM-2 may be attached to the display panel DP via an adhesive layer.

Additional or alternative to the example illustrated in FIG. 3, an adhesive layer may be further disposed between the window WM and the anti-reflective layer UM-1, and an adhesive layer may be further disposed between the anti-reflective layer UM-1 and the input sensor UM-2. The window WM, the anti-reflective layer UM-1, and the input sensor UM-2 may be respectively bonded through the adhesive layers.

In an embodiment, the circuit board DC may include a flexible board CF and a main board MB. The flexible board CF according to an embodiment may be assembled in a bent state. Accordingly, the main board MB may be disposed on a lower surface of the display panel DP to be stably accommodated in a space supplied by a housing HU (see FIG. 2). For example, the flexible board CF may be bent toward a rear surface of the display panel DP, and may be disposed under the protective layer PL.

In an embodiment, the protective layer PL may include a first protection portion PL1 and a second protection portion PL2. The first protection portion PL1 and the second protection portion PL2 may be each disposed on a lower surface DP-LF of the display panel DP. The first protection portion PL1 may correspond to at least a display region AA of the display panel DP. The second protection portion PL2 may correspond to at least a pad region PA of the display panel DP.

The first protection portion PL1 may overlap the display region AA. The first protection portion PL1 may be disposed on the lower surface DP-LF of the display panel DP to overlap the display region AA. For example, the first protection portion PL1 may be disposed such that the first protection portion PL1 overlaps the display region AA. The second protection portion PL2 may overlap at least the pad region PA. The second protection portion PL2 may be disposed on the lower surface DP-LF of the display panel DP to overlap the pad region PA. For example, the second protection portion PL2 may be disposed such that the second protection portion PL2 overlaps the pad region PA. A more detailed description of the first protection portion PL1 and the second protection portion PL2 will be made with reference to additional figures described herein, for example, with reference to FIG. 5A.

The protective layer PL may be in contact with the circuit board DC. According to an embodiment, the display module DM, the window WM, and one or more other components of the display device DD may be assembled in a state in which the flexible board CF is bent. In this example state, the protective layer PL may be in contact with the main board MB. The protective layer PL may include an upper surface adjacent to the display panel DP and a lower surface opposed to the upper surface. For example, the upper surface and the lower surface may face opposite directions. The lower surface of the protective layer PL may be in contact with the circuit board DC. For example, the first protection portion PL1 of the protective layer PL may be in contact with the circuit board DC.

FIG. 4 is a cross-sectional view of a display panel DP according to an embodiment.

In an embodiment, the display panel DP includes a base substrate BL, a circuit layer DP-CL disposed on the base substrate BL, a light-emitting element layer DP-ED, and an encapsulation layer ENL. The base substrate BL may include a plastic substrate, a glass substrate, a metal substrate, an organic/inorganic composite material substrate, or the like. For example, the base substrate BL may include at least one polyimide layer.

The circuit layer DP-CL includes at least one insulating layer, semiconductor patterns, and conductive patterns. The insulating layer includes at least one inorganic layer and at least one organic layer. The semiconductor patterns and the conductive patterns may constitute signal lines, a pixel-driving circuit, and a scan-driving circuit. In some embodiments, the circuit layer DP-CL may include a back metal layer.

The light-emitting element layer DP-ED includes a display element, for example, a light-emitting element. For example, the light-emitting element may be an organic light-emitting element, a quantum dot light-emitting element, a micro-LED light-emitting element, or a nano-LED light-emitting element. The light-emitting element layer DP-ED may further include an organic layer such as, for example, a pixel-defining film.

The light-emitting element layer DP-ED may be disposed in a display region AA. A non-display region NAA may be disposed outside the display region AA and surround the display region AA. The light-emitting element may be disposed such that the light-emitting element is not in the non-display region NAA.

The encapsulation layer ENL may be disposed on the light-emitting element layer DP-ED to cover the light-emitting element layer DP-ED. For example, the encapsulation layer ENL may cover the light-emitting element layer DP-ED. The encapsulation layer ENL may be disposed on the circuit layer DP-CL to seal the light-emitting element layer DP-ED. For example, the encapsulation layer ENL may seal the light-emitting element layer DP-ED. The encapsulation layer ENL may be a thin-film encapsulation layer including a plurality of organic thin films and a plurality of inorganic thin films. In an example, the encapsulation layer ENL may include a thin film encapsulation layer including a stack structure of an inorganic layer/organic layer/inorganic layer, but the stack structure of the encapsulation layer ENL is not specially limited thereto. For example, the stack structure of the encapsulation layer ENL may include a combination of inorganic layer(s) and/or organic layer(s) different from the example combination of an inorganic layer/organic layer/inorganic layer.

FIG. 5A is an enlarged cross-sectional view illustrating region AA illustrated in FIG. 3. FIG. 5A is a cross-sectional view specifically illustrating a first protection portion PL1 included in a protective layer PL according to an embodiment. FIG. 5B is an enlarged cross-sectional view illustrating region BB illustrated in FIG. 3. FIG. 5B is a cross-sectional view specifically illustrating a second protection portion PL2 included in the protective layer PL according to an embodiment.

Referring to FIGS. 3, 5A, and 5B, a display device DD according to an embodiment of the inventive concept may include a display panel DP and the protective layer PL disposed under the display panel DP. In the display device according to an example embodiment of the inventive concept, the display device DD may be implemented such that only the protective layer PL is disposed under the display panel DP. For example, the lowermost surface of the display module DM may be defined as the lowermost surface of the protective layer PL. Accordingly, in some embodiments (e.g., in which only the protective layer PL is disposed under the display panel DP), the display device DD may have a reduced thickness and may have simplified parts, and thus process efficiency during manufacture of the display device DD may be increased.

The protective layer PL may include the first protection portion PL1 overlapping a display region AA of the display panel DP, and a second protection portion PL2 overlapping at least a pad region PA of a non-display region NAA of the display panel DP. The protective layer PL may be directly disposed under the display panel DP. The protective layer PL may be in contact with the lower surface DP-LF of the display panel DP. According to one or more embodiments of the present disclosure, the display device DD may be implemented without disposing a separate adhesive member between the protective layer PL and the display panel DP. For example, a separate adhesive member may not be disposed between the protective layer PL and the display panel DP. The first protection portion PL1 may be directly disposed under the display panel DP to overlap the display region AA. For example, the first protection portion PL1 may be disposed such that the first protection portion PL1 overlaps the display region AA. The second protection portion PL2 may be directly disposed under the display panel DP to overlap the pad region PA. For example, the second protection portion PL2 may be disposed such that the second protection portion PL2 overlaps the pad region PA.

The first protection portion PL1 and the second protection portion PL2 may be disposed parallel along the second direction DR2. In an example, the first protection portion PL1 and the second protection portion PL2 may be adjacent in the second direction DR2. The first protection portion PL1 may include one end PL-S1 (see FIG. 2) adjacent to the pad region PA and another end PL-S2 (see FIG. 2) opposed to the one end PL-S1 (see FIG. 2). For example, the one end PL-S1 and the other end PL-S2 may face opposite directions. The one end PL-S1 (see FIG. 2) of the first protection portion PL1 adjacent to the pad region PA may be in contact with the second protection portion PL2. In some embodiments, on a plane defined by the first direction DR1 and the second direction DR2, the first protection portion PL1 and the second protection portion PL2 may be disposed such that the first protection portion PL1 and the second protection portion PL2 do not overlap each other.

The first protection portion PL1 and the second protection portion PL2 may be respectively provided by separate processes. For example, in some embodiments, the protective layer PL may be formed by supplying a resin for producing the first protection portion PL1 and a resin for producing the second protection portion PL2 onto the lower surface DP-LF of the display panel DP through separate respective processes. The first protection portion PL1 may be formed on a portion of the lower surface DP-LF of the display panel DP corresponding to the display region AA, and the second protection portion PL2 may be formed on a portion of the lower surface DP-LF of the display panel DP corresponding to the pad region PA. In an embodiment, the second protection portion PL2 may be a component formed after a pressure mark test in a process for manufacturing a display device.

The pad region PA of the display panel DP may be a region in which an electronic element such as, for example, a driving chip DDV or a circuit board DC is disposed. The pad region PA may be a region in which the driving chip DDV and the circuit board DC are electrically connected to the display panel DP. The electronic element may be disposed to be electrically connected to a wire and/or a pad disposed in the pad region PA of the display panel DP.

Aspects of the present disclosure support the manufacture of the display device DD, in which a pressure mark test (or other verification test) is performed to inspect whether an electronic element disposed in the pad region PA is accurately electrically connected to the display panel DP. For example, when the display device DD is manufactured, the pressure mark test (or other verification test) may be performed to inspect whether or not the driving chip DDV or the circuit board DC is accurately electrically connected to the display panel DP. In some cases, if the display panel DP is not accurately inspected, defects associated with the display device DD in which the driving chip DDV or the circuit board DC is not normally bonded to the pads of the display panel DP may be overlooked. For example, when whether or not the driving chip DDV or the circuit board DC is normally bonded to the pads of the display panel DP is not accurately inspected, failure of the display device DD may result.

In an example, in some other display panels, if a portion corresponding to at least the pad region PA of the protective layer PL is opaque, it may be difficult to determine whether or not the circuit board DC is normally mounted. Accordingly, for example, aspects of the present disclosure include implementing the protective layer PL such that a portion of the protective layer PL corresponding to the pad region PA has high light-transmitting properties, which may support performing a pressure mark test as described herein. According to one or more embodiments of the present disclosure, since the second protection portion PL2 of the protective layer PL overlapping the pad region PA is formed after performing the pressure mark test, a bonding state of the circuit board DC may be efficiently inspected, which may thereby reduce a failure rate of the display device DD.

Referring to FIGS. 3 and 5A, the first protection portion PL1 may be a component that is disposed under the display panel DP to absorb impacts applied to the display panel DP and to dissipate heat generated by the display panel DP. In an example, the first protection portion PL1 is disposed overlapping the display region AA, which corresponds to most of the regions of the display device DD, and the heat generated by the display panel DP may be effectively dissipated by the first protection portion PL1.

In an embodiment, the first protection portion PL1 may include a heat dissipation material HCP. The heat dissipation material HCP included in the first protection portion PL1 may include, for example, at least one among a thermally conductive metal, a carbon-based heat dissipation material, and a thermally conductive polymer. In an example, the heat dissipation material HCP included in the first protection portion PL1 may include a thermally conductive metal such as, for example, aluminum, copper, silver, or magnesium. Alternatively or additionally, the heat dissipation material HCP included in the first protection portion PL1 may include a carbon-based heat dissipation material such as, for example, graphene, graphite, or carbon-nanotube. Alternatively or additionally, the heat dissipation material HCP included in the first protection portion PL1 may include a thermally conductive polymer such as, for example, ultra-high molecular polyethylene.

An average diameter of the heat dissipation material HCP may be equal to or less than about 200 μm. For example, the average diameter of the heat dissipation material HCP may be about 5 μm to about 200 μm. FIG. 5A illustrates an example in which the heat dissipation materials HCP have the same diameter. However, embodiments supported by aspects of the present disclosure are not limited thereto. For example, the heat dissipation material HCP may have a size distribution which is a substantially monodispersed distribution. In another example, the heat dissipation material HCP may have a size distribution which is a polydispersed distribution obtained by mixing a plurality of particles having a monodispersed distribution.

In some cases, when the average diameter of the heat dissipation material HCP is less than about 5 μm, performing heat dissipation characteristics of the protective layer PL may become difficult. In some other cases, when the average diameter of the heat dissipation material HCP is greater than about 200 μm, dispersion characteristics of the heat dissipation material HCP in the first protection portion PL1 may be deteriorated, and securing uniform thin film characteristics may become difficult. Accordingly, for example, implementations described herein in which the average diameter of the heat dissipation material HCP ranges from about 5 μm to about 200 μm may support improved heat dissipation characteristics of the protective layer PL, improved dispersion characteristics of the heat dissipation material HCP, and uniform thin film characteristics. In some embodiments, the heat dissipation material HCP may be used by mixing at least two materials having different types or sizes. For example, the heat dissipation material HCP may include at least two materials of different type and/or size.

The heat dissipation material HCP may have various shapes. FIGS. 5A and 5B illustrate the heat dissipation material HCP as a particle, in which the cross-section of the particle is an ellipse. However, the illustrated shape is provided as an example for convenience of description, and the shape of the particle is not limited thereto. For example, particles of the heat dissipation material HCP may be of any suitable shape supportive of the described functions and characteristics of the heat dissipation material HCP. For example, the illustrated shape is not to be limited as a substantial form of the heat dissipation material HCP.

The heat dissipation material HCP may be included in an amount of about 85 wt % or less with respect to the total weight of the first protection portion PL1. For example, the heat dissipation material HCP may be included in an amount of about 60 wt % to about 85 wt % with respect to the total weight of the first protection portion PL1. In some cases, when a content of the heat dissipation material HCP is less than about 60 wt %, the heat dissipation characteristics of the first protection portion PL1 may be reduced. In some other cases, when the content of the heat dissipation material HCP is greater than about 85 wt %, impact absorbing characteristics of the first protection portion PL1 may be excessively deteriorated, and thus the impact absorbing characteristics of the entire protective layer PL are deteriorated, and the display panel DP may be susceptible to damage due to an external impact. Accordingly, for example, implementations described herein in which the heat dissipation material HCP is included in an amount of about 60 wt % to about 85 wt % with respect to the total weight of the first protection portion PL1 may support improved heat dissipation characteristics of the first protection portion PL1, improved impact absorbing characteristics of the first protection portion PL1, and improved impact absorbing characteristics of the entire protective layer PL.

In an embodiment, the first protection portion PL1 may further include a light-blocking material BP. The first protection portion PL1 may include the light-blocking material BP, and therefore may have a black color. The light-blocking material BP included in the first protection portion PL1 may be, for example, a black pigment or a black dye. Alternatively, the light-blocking material BP included in the first protection portion PL1 may be a carbon-based material such as, for example, graphene or graphite. In an example in which the first protection portion PL1 includes the light-blocking material BP, the protective layer PL may block light emitted by the display panel DP from leaking downward from the display panel DP. That is, for example, the protective layer PL may perform a function of protecting the display panel DP from an external impact, and also a function of blocking the light emitted by the display panel DP. Accordingly, in some example embodiments, the protective layer PL included in the display device DD may be implemented without a separate light-blocking sheet (e.g., the protective layer PL may not include a separate light-blocking sheet). According to one or more embodiments of the present disclosure, by implementing the display device DD such that the protective layer PL does not include the separate light-blocking sheet, a thickness of the protective layer PL may be reduced. Accordingly, the display device DD may be lightweight and thin. The terms “does not include” and “is absent” may be used interchangeably herein.

In an embodiment, the first protection portion PL1 may further include at least one of a blowing agent and an elastic hollow particle. For example, the first protection portion PL1 may further include a blowing agent PR. According to one or more embodiments of the present disclosure, since the blowing agent PR or the elastic hollow particle is included in the first protection portion PL1, the impact absorbing characteristics of the first protection portion PL1 may be improved. In some cases, when the first protection portion PL1 includes a particulate additive such as, for example, the heat dissipation material HCP, the impact absorbing characteristics of the first protection portion PL1 may be deteriorated. However, since the first protection portion PL1 according to an embodiment includes the blowing agent or the elastic hollow particle for absorbing an impact, deterioration of the impact absorbing characteristics of the first protection portion PL1 may be mitigated or prevented, and therefore deterioration of the impact absorbing characteristics of the protective layer PL may be prevented.

In some embodiments, the first protection portion PL1 may further include a first base resin RS1. In an embodiment, the first base resin RS1 may include at least one of an acrylic resin, a urethane-based resin, a fluorine-based resin, an epoxy-based resin, a polyester-based resin, a polyamide-based resin, and a silicone-based resin.

In an embodiment, the first protection portion PL1 may further include an additive. In some examples, the additive may be a thermal initiator or a photoinitiator.

In an embodiment, the first protection portion PL1 may include the first base resin RS1, and the heat dissipation material HCP, the light-blocking material BP, and the blowing agent PR which are dispersed in the first base resin RS1. According to one or more embodiments of the present disclosure, since the first protection portion PL1 includes the first base resin RS1, the heat dissipation material HCP, the light-blocking material BP, and the blowing agent PR, the first protection portion PL1 may perform multiple-functions in the display device DD. For example, the first protection portion PL1 may support the display panel DP. The first protection portion PL1 may protect the display panel DP and other components of the display device DD from a physical impact applied from the outside. In some aspects, the protective layer PL may perform a heat dissipation function of dissipating heat generated by the display panel DP or other components of the display device DD. The first protection portion PL1 may perform a light-blocking function of blocking light emitted by the display panel DP. However, embodiments supported by aspects of the present disclosure are not limited thereto, and according to characteristics such as, for example, a material included in the first protection portion PL1, a thickness of the first protection portion PL1, or the like, the first protection portion PL1 may additionally perform other functions in the display device DD. For example, the first protection portion PL1 may further include a material having a blocking function. In an example, the first protection portion PL1 includes an electromagnetic blocking material, and the first protection portion PL1 may have a function of blocking electromagnetic waves, or the like.

Referring to FIGS. 3 and 5B, the second protection portion PL2 may be disposed under the display panel DP to overlap the pad region PA on a plane. For example, the second protection portion PL2 may be disposed under the display panel DP and overlap the pad region PA on the plane. The second protection portion PL2 may be directly disposed on a lower surface of the display panel DP to overlap the pad region PA. For example, the second protection portion PL2 may be directly disposed on the lower surface of the display panel DP and overlap the pad region PA. The second protection portion PL2 may include at least one of the light-blocking material BP and the blowing agent PR.

According to one or more embodiments of the present disclosure, the second protection portion PL2 may be provided such that, in the second direction DR2, a width of the second protection portion PL2 is smaller than a width of the pad region PA of the display panel DP. The second protection portion PL2 may include one end PL-S3 adjacent to the display region AA and another end PL-S4 opposed to the one end PL-S3. The other end PL-S4 of the second protection portion PL2 may not align with a side surface of the display panel DP adjacent to the pad region PA. For example, since the width of the second protection portion PL2 is smaller than the width of the pad region PA of the display panel DP, the other end PL-S4 of the second protection portion PL2 may be disposed more inward than the side surface of the display panel DP adjacent to the pad region PA. However, embodiments supported by aspects of the present disclosure are not limited thereto, and the second protection portion PL2 may be provided such that the width of the second protection portion PL2 is equal to the width of the pad region PA of the display panel DP in the second direction DR2, and in this case, the other end PL-S4 of the second protection portion PL2 may align with the one side surface of the display panel DP adjacent to the pad region PA.

In an embodiment, the second protection portion PL2 may include the light-blocking material BP. The second protection portion PL2 may include the light-blocking material BP and thus have a black color. The light-blocking material BP included in the second protection portion PL2 may be, for example, a black pigment or a black dye. Alternatively or additionally, the light-blocking material BP included in the second protection portion PL2 may be a carbon-based material such as, for example, graphene or graphite.

In an embodiment, the second protection portion PL2 may further include at least one of a blowing agent and an elastic hollow particle. For example, the second protection portion PL2 may further include a blowing agent PR. Since the blowing agent PR or the elastic hollow particle is included in the second protection portion PL2, impact absorbing characteristics of the second protection portion PL2 may be improved. Since the second protection portion PL2 according to an embodiment includes the blowing agent or the elastic hollow particle for absorbing an impact, the impact absorbing characteristics of the protective layer PL may be improved.

The second protection portion PL2 may further include a second base resin RS2. The second base resin RS2 may serve to disperse the light-blocking material BP and the blowing agent PR. The light-blocking material BP and the blowing agent PR may be provided such that the light-blocking material BP and the blowing agent PR are dispersed in the second base resin RS2. In an embodiment, the second base resin RS2 may include at least one of an acrylic resin, a urethane-based resin, a fluorine-based resin, an epoxy-based resin, a polyester-based resin, a polyamide-based resin, and a silicone-based resin.

In an embodiment, the second protection portion PL2 may further include an additive. The additive may be a thermal initiator or a photoinitiator.

In an embodiment, the second protection portion PL2 may include the second base resin RS2, and the light-blocking material BP and the blowing agent PR which are dispersed in the second base resin RS2. In an embodiment, the second protection portion PL2 does not include a heat dissipation material. The second protection portion PL2 may include the second base resin RS2, the light-blocking material BP, the blowing agent PR, and an additive. For example, in an embodiment, the second protection portion PL2 may be composed of the second base resin RS2, the light-blocking material BP, the blowing agent PR, and an additive. The second protection portion PL2 may include the second base resin RS2, the light-blocking material BP, the blowing agent PR, and an initiator. For example, in an embodiment, the second protection portion PL2 may be composed of the second base resin RS2, the light-blocking material BP, the blowing agent PR, and an initiator. The second protection portion PL2 may be a single layer composed of the second base resin RS2, the light-blocking material BP, the blowing agent PR, and the additive.

According to one or more embodiments of the present disclosure, in an example in which the second protection portion PL2 includes the second base resin RS2, the light-blocking material BP, and the blowing agent PR, the second protection portion PL2 may perform multiple-functions in the display device. For example, the second protection portion PL2 may support the display panel DP. The second protection portion PL2 may protect the display panel DP or other components of the display device DD from a physical impact applied from the outside. In some aspects, the second protection portion PL2 may perform a light-blocking function. The second protection portion PL2 may be disposed partially or entirely overlapping the pad region PA. Accordingly, for example, the second protection portion PL2 may perform a light-blocking function associated with preventing a component disposed in the pad region PA from being viewed from the outside. Alternatively or additionally, the second protection portion PL2 may further include a material having a blocking function. In an example, the second protection portion PL2 includes an electromagnetic blocking material, and the second protection portion PL2 may have a function of blocking electromagnetic waves, or the like. However, embodiments supported by aspects of the present disclosure are not limited thereto, and according to characteristics such as, for example, a thickness, or a material of the second protection portion PL2, the second protection portion PL2 may additionally perform other functions in the display device.

The first protection portion PL1 and the second protection portion PL2 may each have a thickness of about 50 μm to about 200 μm. For example, the first protection portion PL1 and the second protection portion PL2 may each have a thickness of about 100 μm to about 200 μm. In an embodiment, the thickness of the second protection portion PL2 may be equal to or smaller than the thickness of the first protection portion PL1. For example, the thickness of the first protection portion PL1 and the thickness of the second protection portion PL2 may be substantially the same.

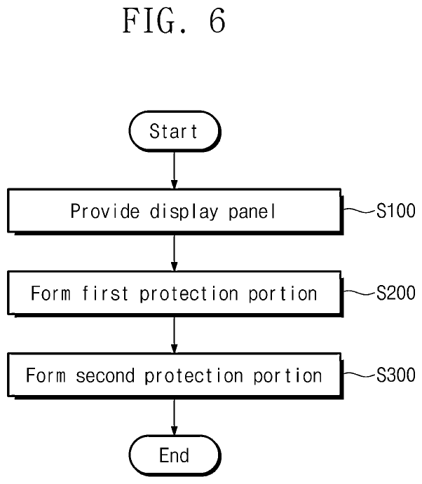

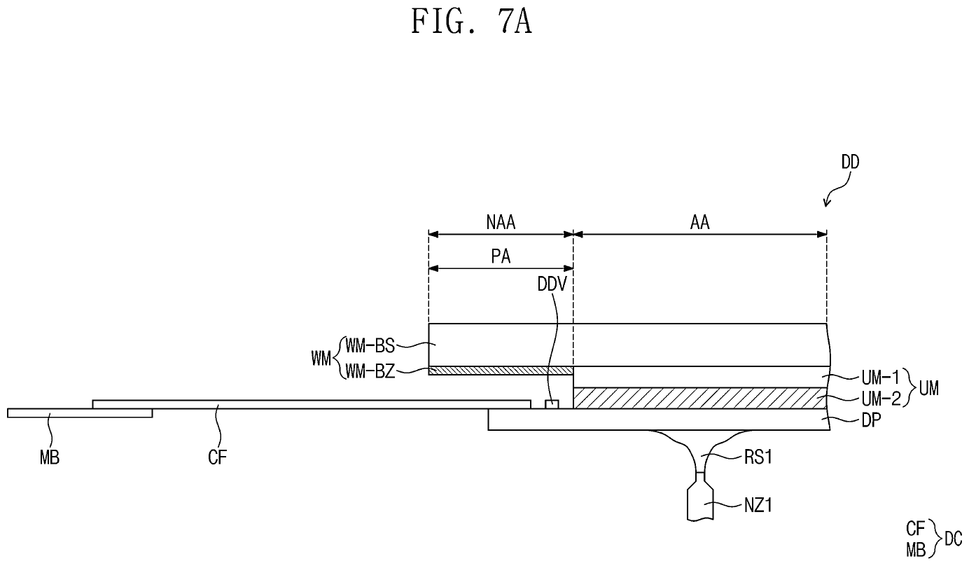

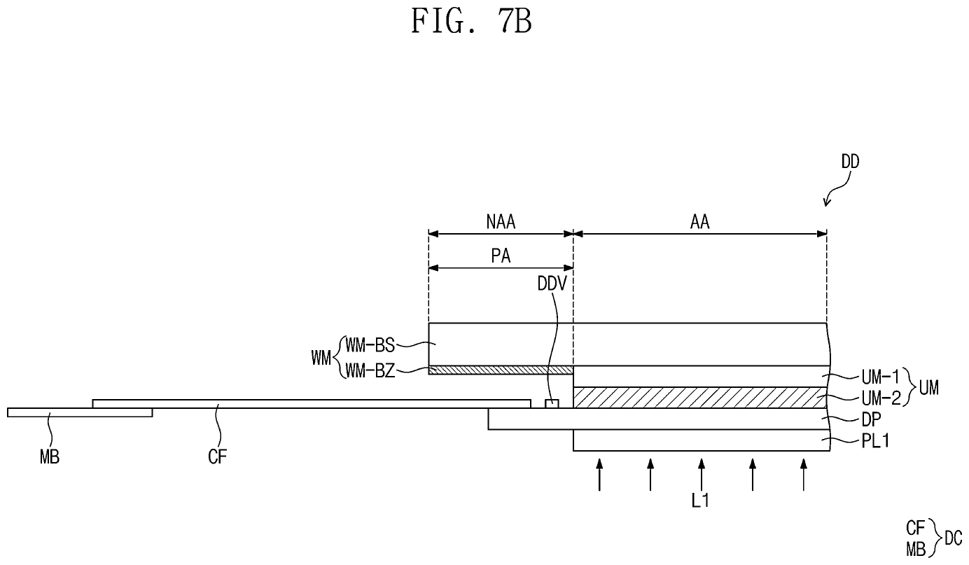

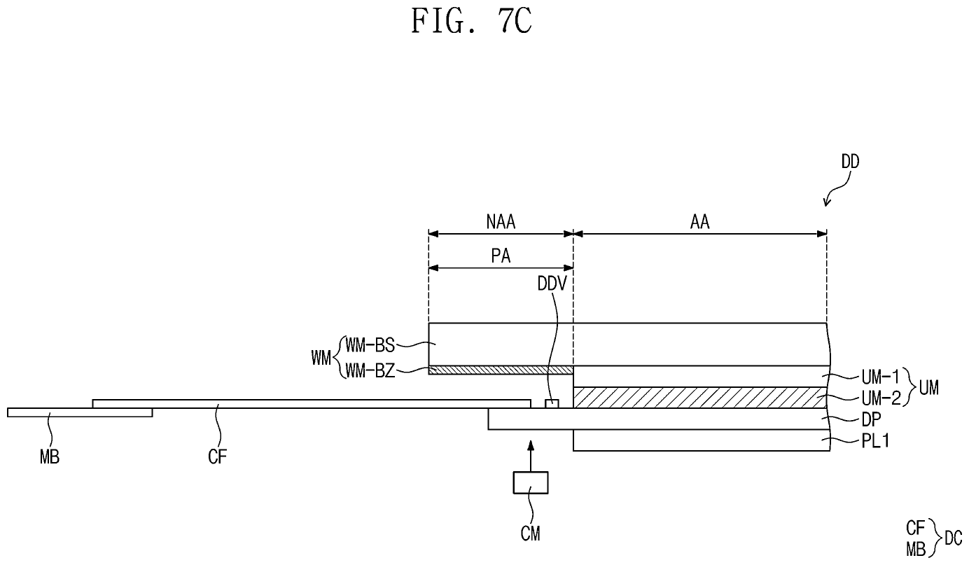

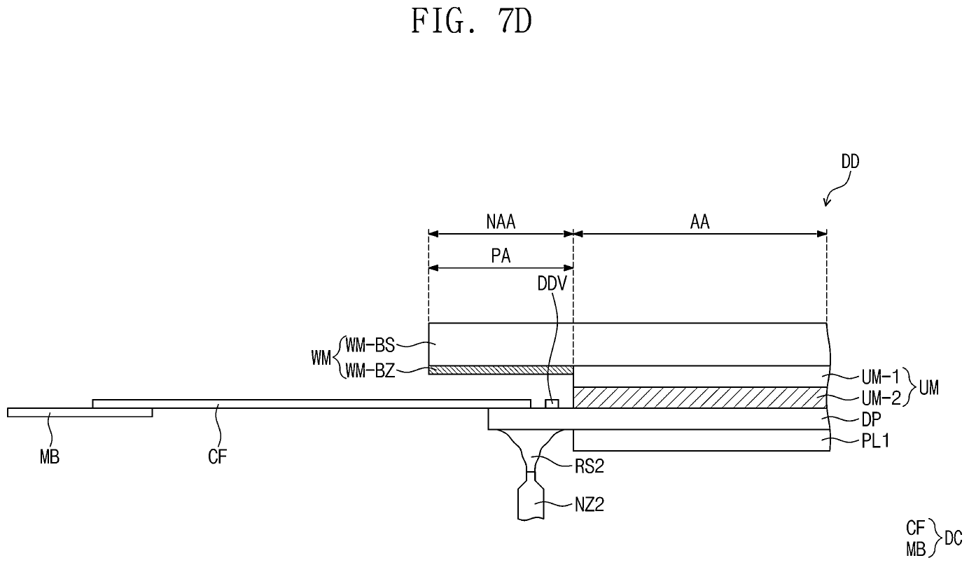

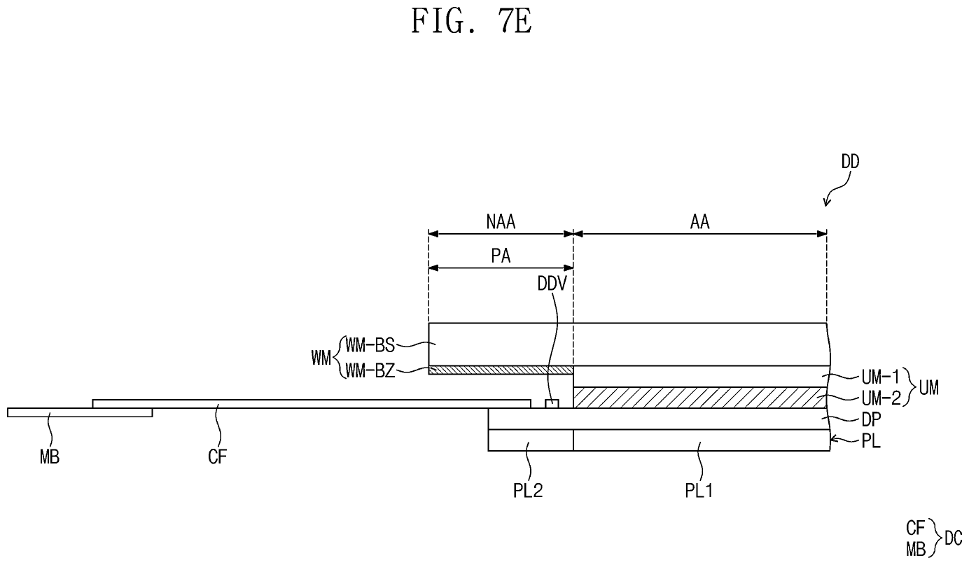

FIG. 6 is a flowchart illustrating a method for manufacturing a display device according to an embodiment. FIGS. 7A to 7E are cross-sectional views illustrating some operations of a method for manufacturing a window according to one or more embodiments of the inventive concept. According to one or more embodiments of the present disclosure, the method for manufacturing a display device as described herein may support manufacturing a display device DD according to at least the embodiments described in FIGS. 1 to 5B. An embodiment provides a method for manufacturing a display device including a protective layer PL disposed under a display panel DP. Hereinafter, in describing the method for manufacturing a display device DD according to an embodiment with reference to FIG. 6 and FIGS. 7A to 7E, the same reference numerals or symbols will be used for the same components as those described previously, and detailed description thereof will be omitted.

Referring to FIG. 6, the method for manufacturing a display device according to an embodiment includes an operation (S100) of providing a display panel, an operation (S200) of forming a first protection portion, and an operation (S300) of forming a second protection portion. In the descriptions of the method herein, the operations may be performed in a different order than the order shown, or the operations may be performed in different orders or at different times. Certain operations may also be left out of the method, one or more operations may be repeated, or other operations may be added to the method.

FIG. 7A schematically illustrates the operation (S200) of forming a first protection portion PL1 by supplying a first resin RS1 onto a lower surface of a display panel DP to overlap a display region. For example, the first protection portion PL1 formed in accordance with example aspects of the present disclosure may overlap the display region.

Referring to FIG. 7A, a first resin RS1 may be applied onto the lower surface of a display panel DP through a first nozzle NZ1. The first resin RS1 may be supplied onto a portion corresponding to a display region AA in the display panel DP. The first resin RS1 may be entirely supplied onto the display region AA. For example, the operation (S200) may include supplying the first resin RS1 onto all portions of the display panel DP which overlap the display region AA in a plan view. In some embodiments, the first resin RS1 may be supplied onto the display region AA and a non-display region NAA excluding the pad region PA. In an example, the operation (S200) may include refraining from supplying the first resin RS1 onto the pad region PA. For example, the first resin RS1 may not be supplied onto the pad region PA. In an embodiment, the first resin RS1 may be directly applied onto the display panel DP. Accordingly, in the example embodiment, the display panel DP and the first protection portion PL1 formed thereafter may be implemented without an additional adhesive layer between the display panel DP and the first protection portion PL1, thereby improving the processability of the display device.

The operation (S200) of forming the first protection portion PL1 may be performed in various ways. For example, the operation (S200) of forming the first protection portion PL1 may be performed by at least one of spin coating, slit coating, jet printing, metal mask printing, and screen printing. In an example, the operation (S200) of forming the first protection portion PL1 may be performed by screen printing.

The first resin RS1 may include a heat dissipation material. The first resin RS1 may include a first base resin, and the heat dissipation material dispersed in the first base resin. The first base resin may include at least of an acrylic resin, a urethane-based resin, a fluorine-based resin, an epoxy-based resin, a polyester-based resin, a polyamide-based resin, and a silicone-based resin. The first base resin may include, in a form of a monomer or oligomer, an acrylic resin, a urethane-based resin, a fluorine-based resin, an epoxy-based resin, a polyester-based resin, a polyamide-based resin, or a silicone-based resin. The first base resin included in the first resin RS1 may have a liquid phase before curing.

In an embodiment, the first resin RS1 may further include at least one of a light-blocking material and a blowing agent, in addition to the heat dissipation material. For example, the first resin RS1 may include the first base resin, in which the heat dissipation material, the light-blocking material, and the blowing agent are dispersed in the first base resin. However, embodiments supported by aspects of the present disclosure are not limited thereto, and the first resin RS1 may further include an additional additive such as, for example, an electromagnetic blocking material.

FIG. 7B is a diagram schematically illustrating an operation of curing the first resin RS1.

Referring to FIG. 7B, the operation of curing the first resin RS1 may be an operation of forming the first protection portion PL1 by supplying first light L1 to the first resin RS1. For example, the operation of curing the first resin RS1 may be included in the operation (S200) of forming the first protection portion PL1. The first resin RS1 may be cured by supplying the first light L1 to the first resin RS1 supplied on the lower surface of the display panel DP. The first light L1 may include ultraviolet rays. For example, the first light L1 may be ultraviolet rays having a central wavelength in a wavelength range of about 100 nm to about 400 nm. The first resin RS1 may be photocured upon being exposed to the first light L1. Although FIG. 7B illustrates an example in which the first resin RS1 is cured by light, embodiments supported by aspects of the present disclosure are not limited thereto, and the first resin RS1 may be a resin cured by thermally curing.

FIG. 7C is a diagram schematically illustrating an operation of determining whether or not a circuit board DC is normally mounted.

Referring to FIG. 7C, the operation of determining whether or not a circuit board DC is normally mounted may be performed after the operation (S200) of forming the first protection portion PL1. The circuit board DC may be bonded to the pads PD of the display panel DP through an anisotropic conductive film. When the anisotropic conductive film is interposed between the circuit board DC and the display panel DP, and is thermally compressed, a pressure mark may be formed in a bonding portion. For example, the bonding portion may be between the circuit board DC and a pad PD, and one or more pressure marks may be formed in the bonding portion. The operation of determining whether or not the circuit board DC is normally mounted may be an operation of extracting an image of the pressure mark and determining, based on the pressure mark, whether or not there is a bonding defect. For example, the operation of determining whether or not the circuit board DC is normally mounted may be based on analyzing the number of pressure marks, protrusion degrees of the pressure marks, lengths of the pressure mark, a distribution of the pressure marks, or the like. In some embodiments, the circuit board DC may be considered to be normally mounted based on a comparison result of the number of pressure marks, the protrusion degrees of the pressure marks, the lengths of the pressure marks, the distribution of the pressure marks, or the like to a respective threshold value associated with a normal mounting (e.g., absence of a bonding defect) of the circuit board DC.

In an embodiment, whether or not the circuit board DC is normally mounted may be confirmed by using a pressure mark test device CM before forming the second protection portion PL2. For example, the operation of confirming whether or not the circuit board DC is normally mounted may be performed before the operation (S300) of forming the second protection portion PL2, thereby facilitating a test for the pressure mark formed in the pad region PA through the lower surface of the display panel DP. In an example of the pressure mark test, the pressure mark test device CM may be disposed under the display panel DP. The pressure mark test device CM may be disposed under the display panel DP to capture an image of the pad region PA. For example, the pressure mark test device CM may capture one or more images of the pad region PA. The pressure mark test device CM may inspect the pressure mark formed in the pad region PA through the lower surface of the display panel DP. The pressure mark test device CM may capture an image of a pressure mark formed in a bonding portion to confirm whether or not the circuit board DC is normally mounted.

A protective layer PL may be disposed such that the protective layer is not disposed under the display panel DP overlapping the pad region PA in the pressure mark test. The first protection portion PL1 of the protective layer PL may overlap the display region AA (e.g., overlap only the display region AA), without overlapping the pad region PA. According to one or more embodiments of the present disclosure, since the protective layer PL is not disposed in the pad region PA (e.g., second protection portion PL2 has not yet been formed), whether or not the circuit board DC is normally mounted may be easily inspected by using the pressure mark test device CM disposed under the display panel DP. Accordingly, the reliability of determining failure of the display device DD may be improved.

FIG. 7D schematically illustrates the operation (S300) of forming a second protection portion PL2 by supplying the second resin RS2 onto the lower surface of the display panel DP to overlap the pad region PA. For example, the second protection portion PL2 formed in accordance with example aspects of the present disclosure may overlap the pad region PA.

The second resin RS2 for forming the second protection portion PL2 may be supplied after processing a pressure mark test for confirming whether or not the circuit board DC is normally mounted in a display device manufacturing process. For example, in accordance with one or more embodiments of the present disclosure, the operation (S300) may be performed after confirming the circuit board DC is normally mounted in the display device manufacturing process. Referring to FIG. 7D, the second resin RS2 may be applied onto the lower surface of the display panel DP through a second nozzle NZ2. The second resin RS2 may be supplied onto a portion corresponding to at least the pad region PA in the display panel DP. The second resin RS2 may be supplied onto the lower surface of the display panel DP to overlap a driving chip DDV and a circuit board DC disposed in the pad region PA. For example, the operation (S300) may include supplying the second resin RS2 such that the second resin RS2 overlaps the driving chip DDV and the circuit board DC. In an embodiment, the second resin RS2 may be directly applied onto the display panel DP. Accordingly, in the example embodiment, the display panel DP and the second protection portion PL2 formed thereafter may be implemented without a separate adhesive layer between the display panel DP and the second protection portion PL2, thereby improving the processability of the display device DD.

The operation (S300) of forming the second protection portion PL2 may be performed in various ways. For example, the operation (S300) of forming a second protection portion PL2 may be performed by at least one of inkjet printing, slit coating, and jet printing. In an example, by supplying the second resin RS2 for forming the second protection portion PL2 by inkjet printing, slit coating, or jet printing, the second resin RS2 may be uniformly applied onto the pad region PA corresponding to a local region of the display panel DP. Accordingly, for example, the process reliability of the display device DD may be improved.

In an embodiment, the first protection portion PL1 and the second protection portion PL2 may be respectively formed through different processes. The first protection portion PL1 may be formed by at least one of metal mask printing and screen printing (and in some cases, any one among metal mask printing and screen printing), and the second protection portion PL2 may be formed by at least one of inkjet printing, slit coating, and jet printing (and in some cases, any one among inkjet printing, slit coating, and jet printing). However, embodiments supported by aspects of the present disclosure are not limited thereto.

The second resin RS2 may include at least one of a light-blocking material and a blowing agent. In an embodiment, the second resin RS2 may include a second base resin, and the second resin RS2 may include the light-blowing material and the blowing agent which are dispersed in the second base resin. However, embodiments supported by aspects of the present disclosure are not limited thereto, and the first resin RS1 may include one or more additives additional and/or alternative to the example additives described herein. For example, the first resin RS1 may further include an additional additive such as, for example, an electromagnetic blocking material.

In some aspects, the second resin RS2 may include the second base resin, the light-blocking material, and the blowing agent. In an embodiment, the second resin RS2 may be composed of the second base resin, the light-blocking material, and the blowing agent. The second base resin may include at least one of an acrylic resin, a urethane-based resin, a fluorine-based resin, an epoxy-based resin, a polyester-based resin, a polyamide-based resin, and a silicone-based resin. The second base resin may include, in a form of a monomer or oligomer, an acrylic resin, a urethane-based resin, a fluorine-based resin, an epoxy-based resin, a polyester-based resin, a polyamide-based resin, or a silicone-based resin. The second base resin included in the second resin RS2 may have a liquid phase before curing.

In an embodiment, the second resin RS2 may be implemented without a heat dissipation material. For example, the second resin RS2 may be absent a heat dissipation material. In an example, since the second resin RS2 is applied onto the pad region PA corresponding to a relatively small portion compared to the display region AA in the display panel DP, a process such as, for example, inkjet printing, slit coating, or jet printing may be used. For example, when the second resin RS2 includes a heat dissipation material, nozzle clogging, non-uniform surface formation, etc., may occur due to the heat dissipation material. According to one or more embodiments of the present disclosure, by excluding the heat dissipation material from the second resin RS2 for forming the second protection portion PL2, the techniques described herein support improved applicability of the second resin RS2, prevention of nozzle clogging, and formation of uniform thin film, thereby improving the process reliability of the display device.

FIG. 7E is a diagram schematically illustrating an operation of curing the second resin.

Referring to FIG. 7E, the operation of curing the second resin RS2 may be an operation of supplying second light to the second resin RS2 to form the second protection portion PL2. For example, the operation of curing the second resin RS2 may be included in the operation (S300) of forming the second protection portion PL2. The second resin RS2 may be cured by supplying the second light to the second resin RS2 supplied onto the lower surface of the display panel DP. The second light may include ultraviolet rays. For example, the second light may be ultraviolet rays having a central wavelength in a wavelength region of about 100 nm to about 400 nm. The second resin RS2 may be photocured upon being exposed to the second light. Although FIG. 7E illustrates an example in which the second resin RS2 is cured by light, embodiments supported by aspects of the present disclosure are not limited thereto, and the second resin RS2 may be a resin cured by thermal curing (e.g., heat).

As described herein, the display device DD according to the example embodiments of the inventive concept includes, under the display panel DP, the protective layer PL that performs multiple-functions, and effects of a reduced thickness and simplified parts of the display device DD may be obtained.

Example aspects of the display device DD described herein provide features for addressing various side-effects which may occur in display panels that include a light-emitting element. For example, some other display devices may include, under a display panel, various members such as, for example, a blocking layer, a heat dissipation layer, a cushion layer, or a support layer to solve such side-effects. On the contrary, in accordance with one or more example embodiments of the inventive concept, the protective layer PL described herein as disposed under the display panel DP is capable of performing one or more of the foregoing functions (e.g., of the blocking layer, the heat dissipation layer, the cushion layer, and/or the support layer). In some embodiments, the techniques described herein use a single protective layer PL, which, though capable of performing the same functions achieved through a plurality of layers in other display devices, further provides advantageous effects of reducing thickness, simplifying parts, and improving manufacturing process efficiency for a display device DD. In the display device DD according to example embodiments of the inventive concept, the protective layer PL is disposed under the display panel DP, and therefore the impact resistance of the display panel DP against external impacts may be increased.

In the display device DD according to an embodiment of the inventive concept, the protective layer PL includes the first protection portion PL1 overlapping the display region AA, and the second protection portion PL2 overlapping at least the pad region PA, and thus the process reliability of the display panel DP may be improved. The second protection portion PL2 overlapping the pad region PA, corresponding to a pressure mark test region, of the protective layer PL may be provided through a process separate from a process for forming the first protection portion PL1. For example, the second protection portion PL2 may be formed after a pressure mark test. In accordance with example embodiments of the inventive concept described herein, since the second protection portion PL2 of the protective layer PL overlapping the pad region PA is formed after the pressure mark test, a bonding state of the circuit board DC may be efficiently inspected, and therefore a failure rate of the display device DD may be reduced. In some aspects, since the first protection portion PL1 overlapping the display region AA occupying most of regions of the display panel DP includes a heat dissipation material, the protective layer PL may effectively dissipate heat generated by the display panel DP, thereby improving the reliability of the display device DD. In some other aspects, since the second protection portion PL2 does not include a heat dissipation material, a resin may be uniformly applied onto the pad region PA corresponding to a local region of the display panel DP in a process for forming the second protection portion PL2, and nozzle clogging (e.g., associated with applying the second resin RS2 and forming the second protection portion PL2) may be prevented, thereby improving the process reliability of the display device DD.

According to example embodiments of the inventive concept, when a protective layer PL is disposed under a display panel DP in a display device DD, heat generated by the display panel DP may be effectively dissipated, and a failure rate during a pressure mark test may be reduced through the use of different materials, or the like, in a portion (e.g., first protection portion PL1 described herein) overlapping a display region AA and a portion (e.g., second protection portion PL2 described herein) at least partially overlapping a pad region PA, thereby improving the reliability of the display device DD.

In the above, description has been made with reference to example and/or preferred embodiments of the inventive concept, but those skilled in the art or those of ordinary skill in the relevant technical field may understand that various modifications and changes may be made to the inventive concept within the scope not departing from the spirit and the technology scope of the inventive concept described in the claims to be described later. Therefore, the technical scope of the inventive concept is not limited to the contents described in the detailed description of the specification, but should be determined by the claims.

What is claimed is:

1. A display device comprising:
a display panel comprising a display region and a pad region adjacent to the display region; and
a protective layer disposed under the display panel,
wherein the protective layer comprises:
a first protection portion overlapping the display region and comprising a heat dissipation material, and
a second protection portion overlapping at least the pad region, wherein the second protection portion is absent the heat dissipation material.

2. The display device of claim 1, wherein the first protection portion and the second protection portion are each directly disposed under the display panel.

3. The display device of claim 1, wherein the heat dissipation material comprises at least one of a thermally conductive metal, a carbon-based heat dissipation material, and a thermally conductive polymer.

4. The display device of claim 1, wherein at least one of the first protection portion and the second protection portion further comprises a light-blocking material.

5. The display device of claim 4, wherein the light-blocking material comprises a carbon-based material, a black pigment, or a black dye, wherein the carbon-based material comprises graphene or graphite.

6. The display device of claim 1, wherein at least one of the first protection portion and the second protection portion further comprises a blowing agent.

7. The display device of claim 1, wherein a thickness of the first protection portion and a thickness of the second protection portion are each about 100 μm to about 200 μm.

8. The display device of claim 1, wherein a thickness of the first protection portion and a thickness of the second protection portion are substantially equal.

9. The display device of claim 1, wherein the second protection portion is composed of a base resin, a light-blocking material, a blowing agent, and an additive.

10. The display device of claim 1, wherein the first protection portion and the second protection portion do not overlap each other on a plane.

11. The display device of claim 1, wherein the first protection portion comprises one end adjacent to the pad region and another end spaced apart from the one end, and the one end of the first protection portion is in contact with the second protection portion.

12. The display device of claim 1, wherein an average diameter of the heat dissipation material is about 5 μm to about 200 μm.

13. The display device of claim 1, further comprising a circuit board electrically connected to the display panel,
wherein the protective layer is in contact with at least a portion of the circuit board.

14. The display device of claim 1, wherein the first protection portion and the second protection portion each further comprise at least one of an acrylic resin, a urethane-based resin, a fluorine-based resin, an epoxy-based resin, a polyester-based resin, a polyamide-based resin, and a silicone-based resin.

15. A display device comprising:
a display panel comprising a display region and a pad region adjacent to the display region; and
a protective layer disposed under the display panel,
wherein the protective layer comprises:
a first protection portion overlapping the display region, and comprising a heat dissipation material, and
a second protection portion overlapping at least the pad region, wherein the second protection portion is composed of a base resin, a light-blocking material, a blowing agent, and an additive.

16. A method for manufacturing a display device, the method comprising:
providing a display panel comprising a display region and a pad region adjacent to the display region;
forming a first protection portion by supplying a first resin onto a lower surface of the display panel, wherein the first protection portion overlaps the display region; and
forming a second protection portion by supplying a second resin onto the lower surface of the display panel, wherein the second protection portion overlaps at least the pad region,
wherein the first resin comprises a heat dissipation material, and the second resin is absent the heat dissipation material.

17. The method of claim 16, wherein the forming of the first protection portion comprises:
applying the first resin onto the lower surface of the display panel; and
curing the first resin.

18. The method of claim 16, wherein the forming of the second protection portion comprises:
applying the second resin onto the lower surface of the display panel; and
curing the second resin.

19. The method of claim 16, wherein the second resin is composed of a base resin, a light-blocking material, a blowing agent, and an additive.

20. The method of claim 16, further comprising, before the forming of the second protection portion:
electrically connecting a circuit board to the display panel; and
determining, through the lower surface of the display panel, whether or not the circuit board is normally mounted.
